(19) United States
(12) Patent Application Publication
(10) Pub. No.: US 2006/0194076 A1
(43) Pub. Date: Aug. 31, 2006

(54) Organic electroluminescent element

(75) Inventor: Fumito Nariyuki, Kanagawa (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD.

(21) Appl. No.: 11/362,050

(22) Filed: Feb. 27, 2006

(30) Foreign Application Priority Data
Feb. 28, 2005 (JP) 2005-55049

(51) Int. Cl. H01L 51/54; H05B 33/14

(52) U.S. Cl. 428/690; 428/917; 313/504; 257/102; 257/103; 257/E51.044; 257/E51.05; 257/E51.051

(57) ABSTRACT

An organic electroluminescent element including one or more organic compound layers including at least one luminescent layer between an anode and a cathode, wherein the luminescent layer includes at least two host compounds and at least two phosphorescent materials, and the phosphorescent materials include a phosphorescent material (D1) that satisfies at least one of the following conditions: (a) when the ionization potential of the phosphorescent material (D1) is defined as Ip(D1) and the minimum value out of the ionization potentials of the at least two host compounds as Ip(H)min, ΔIp1 as defined by ΔIp1=Ip(D1)−Ip(H)min satisfies ΔIp1<0 eV, and (b) when the electron affinity of the phosphorescent material (D1) is defined as Ea(D1) and the maximum value out of the electron affinities of the at least two host compounds as Ea(H)max, ΔEa1 as defined by ΔEa1=Ea(H)max−Ea(D1) satisfies ΔEa1<0 eV.

### CROSS-REFERENCE TO RELATED APPLICATION

This application claims priority under 35 USC 119 from Japanese Patent Application No. 2005-055049, the disclosure of which is incorporated by reference herein.

### BACKGROUND OF THE INVENTION

1. Field of the Invention

The present invention relates to an organic electroluminescent element (hereinafter sometimes referred to as an “organic EL element”, a “luminescent element” or an “EL element”) capable of emitting light by converting electric energy into light.

2. Description of the Related Art

Today, research and development for various display devices is being aggressively pursued and, in particular, organic electroluminescent (EL) elements are attracting attention as promising display devices because high brightness light can be emitted with a low voltage.

A technique of using two or more compounds for the host material of the luminescent layer and using each compound as an electron transporting host or a hole transporting host, thereby realizing reduction of power consumption and enhancement of driving durability, has been disclosed (see, for example, Japanese Patent Application Laid-Open (JP-A) Nos. 2002-313583 and 2002-324673, the disclosures of which are incorporated by reference herein).

However, in the luminescent element described in JP-A Nos. 2002-313583 and 2002-324673, since carriers are trapped by a phosphorescent material, the phosphorescent material inevitably deteriorates due to the carrier, which decreases the driving durability and the light emission efficiency, and therefore, an additional enhancement is desired.

Furthermore, an electroluminescent element is disclosed, in which a luminescent layer includes (1) an electron transporting and/or hole transporting host material, (2) compound A which emits phosphorescence at room temperature and (3) compound B which emits phosphorescence or fluorescence at room temperature, and of which the maximum emission wavelength is longer than the maximum emission wavelength of compound A, and thereby compound B can emit light at a high efficiency (see, for example, JP-A No. 2003-77674, the disclosure of which is incorporated by reference herein). That is, it is found that when compound B that is a phosphorescent compound that does not singularly emit light at a high efficiency or a fluorescent compound that shows various luminescent colors but does not exhibit as high a luminescent efficiency as a phosphorescent compound at any of the luminescent colors is used together with compound A, the constituent element (2) that emits phosphorescence at room temperature, the compound A works as a sensitizer to enhance the luminescence of the compound B. However, in the element described in JP-A No. 2003-77674, the driving durability is insufficient and further improvement is required.

### SUMMARY OF THE INVENTION

The invention is carried out in view of the above-mentioned circumstances and intends to provide an organic electroluminescent element excellent in the driving durability and the luminescent characteristics.

The inventor, after variously studying, found that when at least two host materials and at least two phosphorescent materials are included in a luminescent layer and when energy levels such as the electron affinities and the ionization potentials thereof are set in particular ranges, the high luminescent efficiency can be obtained and the driving durability can be improved.

Thereby, in particular the phosphorescent material can be inhibited from deteriorating owing to carriers, and thereby an organic electroluminescent element excellent in the driving durability and high in the luminescent efficiency can be obtained.

That is, the invention can be achieved according to means described below.

A first aspect of the invention provides an organic electroluminescent element comprising one or more organic compound layers between an anode and a cathode, wherein the one or more organic compound layers include at least one luminescent layer, the luminescent layer comprises at least two host compounds and at least two phosphorescent materials, and the at least two phosphorescent materials include a phosphorescent material (D1) that satisfies at least any one of the following conditions:
(a) when the ionization potential of the phosphorescent material (D1) is defined as Ip(D1) and the minimum value out of the ionization potentials of the at least two host compounds is defined as Ip(H)min, ΔIp1 as defined by ΔIp1=Ip(D1)−Ip(H)min satisfies a relationship of ΔIp1<0 eV, and
(b) when the electron affinity of the phosphorescent material (D1) is defined as Ea(D1) and the maximum value out of the electron affinities of the at least two host compounds is defined as Ea(H)max, ΔEa1 as defined by ΔEa1=Ea(H)max−Ea(D1) satisfies a relationship of ΔEa1<0 eV

### BRIEF DESCRIPTION OF THE DRAWINGS

FIG. 1 is an energy state diagram of an organic electroluminescent element according to the invention.

FIGS. 2A to 2D are energy state diagrams of organic electroluminescent elements according to examples 1 to 3.

### DETAILED DESCRIPTION OF THE INVENTION

[Organic Electroluminescent Element]

An organic electroluminescent element according to the invention is an organic electroluminescent element that has one or more organic compound layers including at least one luminescent layer between an anode and a cathode. The luminescent layer includes at least two host compounds and at least two phosphorescent materials (dopants), and at least one of the phosphorescent materials satisfies any one of the following conditions:
(a) when the ionization potential of the phosphorescent material is defined as Ip(D1) and the minimum value out of the ionization potentials of the at least two host compounds is defined as Ip(H)min, ΔIp1 as defined by ΔIp1=Ip(D1)−Ip(H)min satisfies a relationship of ΔIp1<0 eV, and
(b) when the electron affinity of the phosphorescent material is defined as Ea(D1) and the maximum value out of the electron affinities of the at least two host compounds is defined as Ea(H)max, ΔEa1 as defined by ΔEa1=Ea(H)max−Ea(D1) satisfies a relationship of ΔEa1<0 eV

The organic electroluminescent element according to the invention, when thus configured, can exhibit excellent luminescent characteristics and driving durability

Furthermore, from the viewpoints of the luminescent characteristics and the driving durability, at least one of the phosphorescent materials preferably satisfies the following conditions:
(c) when the ionization potential of the phosphorescent material is defined as Ip(D2) and the minimum value out of the ionization potentials of the at least two host compounds is defined as Ip(H)min, ΔIp2 as defined by ΔIp2=Ip(D2)−Ip(H)min satisfies a relationship of ΔIp2>0 eV, and
(d) when the electron affinity of the phosphorescent material is defined as Ea(D2) and the maximum value out of the electron affinities of the at least two host compounds is defined as Ea(H)max, ΔEa2 as defined by ΔEa2=Ea(H)max−Ea(D2) satisfies a relationship of ΔEa2>0 eV

Furthermore, the organic electroluminescent element according to the invention, from the viewpoint of the driving durability, further preferably satisfies at least one of the relationships 1.2 eV>ΔIp2>0.2 eV and 1.2 eV>ΔEa2>0.2 eV, and particularly preferably satisfies at least one of the relationships 1.2 eV>ΔIp2>0.4 eV and 1.2 eV>ΔEa2>0.4 eV

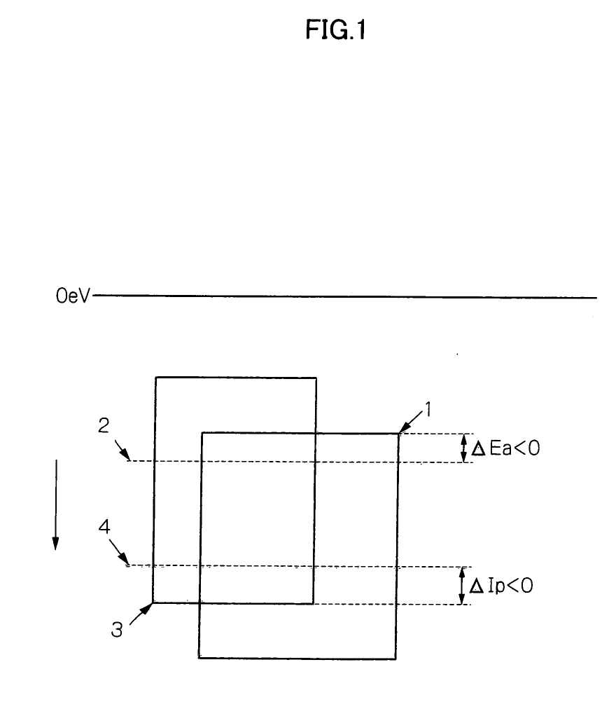

FIG. 1 is a diagram showing an energy state of an organic electroluminescent element according to the invention. In FIG. 1, reference numeral 1 denotes the energy level Ea(H)max of the electron affinity of a second host compound. Reference numeral 2 denotes the energy level Ea(D1) of the electron affinity of a first phosphorescent material. Reference numeral 3 denotes the energy level Ip(H)min of the ionization potential of the first host compound. Reference numeral 4 denotes the energy level Ip(D1) of the ionization potential of the first phosphorescent material.

The ionization potential (Ip), electron affinity (Ea) and triplet level (T₁) (which is described later) as used in the present invention are described below.

The ionization potential (Ip), electron affinity (Ea) and triplet level (T₁), which is described later, are values determined by measuring a single layer film formed on quartz by vacuum-depositing each material.

The ionization potential (Ip) is defined in terms of a value measured at room temperature in air by using an ultraviolet photoelectric analyzer AC-1 (manufactured by Riken Keiki Co., Ltd.). The measurement principle of AC-1 is described in Chihaya Adachi et al., Yuki Hakumaku Sigoto Kansu Data Shu (Work Function Data of Organic Thin Film), CMC (2004), the disclosure of which is incorporated by reference herein.

The electron affinity (Ea) is defined as a value obtained by calculating the band gap from the long wavelength end of the absorption spectrum of the single layer film and calculating the electron affinity (Ea) from the values of the calculated band gap and the above ionization potential.

The lowest triplet excitation energy (triplet level T₁) is defined as a value calculated from the short wavelength end of the phosphorescence emission spectrum measured at room temperature. As for the temperature, the measurement can also be performed at a nitrogen cooled temperature.

The constitution of the organic electroluminescent element of the present invention is described below.

The organic electroluminescent element of the present invention preferably includes one or more organic compound layers including at least one luminescent layer disposed between the anode and the cathode. The organic compound layers preferably further include a carrier transporting layer adjacent to the light-emitting layer. The carrier transporting layer is more preferably an electron transporting layer and/or a hole transporting layer.

In view of the nature of the luminescent element, at least one electrode of the anode and the cathode is preferably transparent.

As for the layer constitution of the organic compound layer in the present invention, in a preferred embodiment, a hole transporting layer, a luminescent layer and an electron transporting layer are disposed in this order from the anode side. Furthermore, an electron blocking layer and the like may be provided between the hole transporting layer and the luminescent layer, and a hole blocking layer and the like may be provided between the luminescent layer and the electron transporting layer. Also, a hole injecting layer may be provided between the anode and the hole transporting layer, and an electron injecting layer may be provided between the cathode and the electron transporting layer.

In the organic electroluminescent element of the present invention, the organic compound layers preferably include at least a hole injecting layer, a hole transporting layer, a luminescent layer, a hole blocking layer, an electron transporting layer and an electron injecting layer in this order from the anode side.

In the case where a hole blocking layer is provided between the luminescent layer and the electron transporting layer, it is preferable that the organic compound layer adjacent to the luminescent layer on the anode side is a hole transporting layer, and the organic compound layer adjacent to the luminescent layer on the cathode side is a hole blocking layer.

Each layer may be divided into a plurality of secondary layers.

The constituents of the luminescent element of the present invention are described in detail below.

<Organic Compound Layer>

The organic compound layer of the present invention is described below.

The organic electroluminescent element of the present invention includes one or more organic compound layers including at least one luminescent layer. Examples of organic compound layers other than the luminescent layer include, as described above, layers such as a carrier transporting layer (hole transporting layer or electron transporting layer) adjacent to the luminescent layer, a hole blocking layer, a hole injecting layer and an electron injecting layer.

From the viewpoint of decreasing the driving voltage, the organic compound layer preferably has a thickness of 50 nm or less, more preferably from 5 to 50 nm, and still more preferably from 10 to 40 nm.

The layer adjacent to the luminescent layer on the anode side may be a hole injecting layer and the layer adjacent to the luminescent layer on the cathode side may be an electron injecting layer or a charge blocking layer. These layers are described in detail below.

(Formation of Organic Compound Layer)

In the organic electroluminescent element of the present invention, the layers constituting the organic compound layer each can be appropriately formed by any of a dry film forming method (e.g., vapor-deposition, sputtering), a transfer method, a printing method or the like.

(Luminescent Layer)

The luminescent layer is a layer having a function of, when an electric field is applied, receiving a hole from the anode, hole injecting layer or hole transporting layer, and receiving an electron from the cathode, electron injecting layer or electron transporting layer, thereby providing a site for the recombination of holes and electrons to emit light.

The luminescent layer for use in the present invention contains at least two phosphorescent materials and at least two host compounds.

The luminescent layer may be a single layer or two or more layers. Each of the two or more layers may emit light with different emission color. When the luminescent element includes a plurality of luminescent layers, each of the luminescent layers preferably contains at least one phosphorescent material and at least two host compounds, and more preferably contains two or more phosphorescent materials.

Examples of the phosphorescent material contained in the luminescent layer in general include complexes containing a transition metal atom or a lanthanoid atom.

The transition metal atom is not particularly limited but preferred examples thereof include ruthenium, rhodium, palladium, tungsten, rhenium, osmium, iridium and platinum. Among these, rhenium, iridium and platinum are more preferred.

Examples of the lanthanoid atom include lanthanum, cerium, praseodymium, neodymium, samarium, europium, gadolinium, terbium, dysprosium, holmium, erbium, thulium, ytterbium and lutecium. Among these lanthanoid atoms, neodymium, europium and gadolinium are preferred.

Examples of the ligand of the complex include ligands described in G Wilkinson et al., Comprehensive Coordination Chemistry, Pergamon Press (1987), H. Yersin, Photochemistry and Photophysics of Coordination Compounds, Springer-Verlag (1987), and Akio Yamamoto, Yuki Kinzoku Kagaku—Kiso to Oyo—(Organometallic Chemistry—Principles and Applications—), Shokabo (1982), the disclosures of which are incorporated by reference herein.

Specifically, the ligand is preferably a halogen ligand (preferably chlorine ligand), a nitrogen-containing heterocyclic ligand (e.g., phenylpyridine, benzoquinoline, quinolinol, bipyridyl, phenanthroline), a diketone ligand (e.g., acetylacetone), a carboxylic acid ligand (e.g., acetic acid ligand), a carbon monoxide ligand, an isonitrile ligand or a cyano ligand, more preferably a nitrogen-containing heterocyclic ligand.

The complex may contain one transition metal atom in the compound or may be a so-called multi-nuclear complex having two or more transition metal atoms. Also, different metal atoms may be contained at the same time.

The luminescent layer in the invention, from a viewpoint of improving the color purity, includes at least two phosphorescent materials as the dopant. As the at least two phosphorescent materials, at least two metal complexes are preferably employed. Furthermore, the at least two metal complexes are preferably metal complexes having a different central metal. From a viewpoint of manufacture of elements, the number of dopants that are phosphorescent materials contained in the luminescent layer is particularly preferably only two.

The phosphorescent materials each, in the luminescent layer, are preferably contained in the range of 0.1 to 20% by mass and, from the viewpoint of the driving durability, more preferably in the range of 0.5 to 10% by mass.

A ratio of contents of the at least two dopants contained in the luminescent layer is not particularly restricted. A ratio of a dopant from which the emission spectrum is derived/other dopants, from the viewpoint of the color purity, is preferably in the range of 100/1 to 1/10, more preferably in the range of 20/1 to 1/5 and still more preferably in the range of 5/1 to 1/2.

At least one of the phosphorescent materials contained in the luminescent layer in the invention satisfies any one of the following conditions:
(a) when the ionization potential of the phosphorescent material is defined as Ip(D1) and the minimum value out of the ionization potentials of the at least two host compounds is defined as Ip(H)min, ΔIp1 as defined by ΔIp1=Ip(D1)−Ip(H)min satisfies a relationship of ΔIp1<0 eV, and
(b) when the electron affinity of the phosphorescent material is defined as Ea(D1) and the maximum value out of the electron affinities of the at least two host compounds is defined as Ea(H)max, ΔEa1 as defined by ΔEa1=Ea(H)max−Ea(D1) satisfies a relationship of ΔEa1<0 eV.

In what follows, the condition in which any one of (a) and (b) is satisfied is called as a condition of (1).

Furthermore, at least one of the phosphorescent materials contained in the luminescent layer in the invention preferably satisfies the following conditions:
(c) when the ionization potential of the phosphorescent material is defined as Ip(D2) and the minimum value out of the ionization potentials of the at least two host compounds is defined as Ip(H)min, ΔIp2 as defined by ΔIp2=Ip(D2)−Ip(H)min satisfies a relationship of ΔIp2>0 eV, and
(d) when the electron affinity of the phosphorescent material is defined as Ea(D2) and the maximum value out of the electron affinities of the at least two host compounds is defined as Ea(H)max, ΔEa2 as defined by ΔEa2=Ea(H)max−Ea(D2) satisfies a relationship of ΔEa2>0 eV.

In what follows, the condition in which (c) and (d) are satisfied is called as a condition of (2).

A phosphorescent material that has the longest emission wavelength, from a viewpoint of the driving durability, preferably satisfies the relationships, further with the host compound, 1.2 eV>ΔIp2>0.2 eV and/or 1.2 eV>ΔEa2>0.2 eV, more preferably of 1.2 eV>ΔIp2>0.4 eV and/or 1.2 eV>ΔEa2>0.4 eV, and particularly preferably of 0.8 eV>ΔIp2>0.4 eV and/or 0.8 eV>ΔEa2>0.4 eV.

The ionization potential Ip and the electron affinity Ea of the phosphorescent material (D1) preferably satisfy the relationships of 4.6 eV<Ip(D1)<7.5 eV and 1.2 eV<Ea(D1)<4.0 eV, and more preferably satisfy the relationships of “4.6 eV<Ip(D1)<5.7 eV and 1.2 eV<Ea(D1)≦2.8 eV” or “5.4 eV≦Ip(D1)<7.1 eV and 2.4 eV<Ea(D1)<4.0 eV”.

The ionization potential Ip and the electron affinity Ea of the phosphorescent material (D2) preferably satisfy the relationships of 4.6 eV<Ip(D2)<7.5 eV and 1.2 eV<Ea(D2)<4.0 eV, and more preferably satisfy the relationships of 5.4 eV≦Ip(D2)<7.1 eV and 1.2 eV<Ea(D2)≦2.8 eV

The phosphorescent materials are not particularly limited, as long as at least one of the phosphorescent materials contained in the luminescent layer satisfies the condition of (1). Specific examples thereof include the following compounds, without restricting thereto.

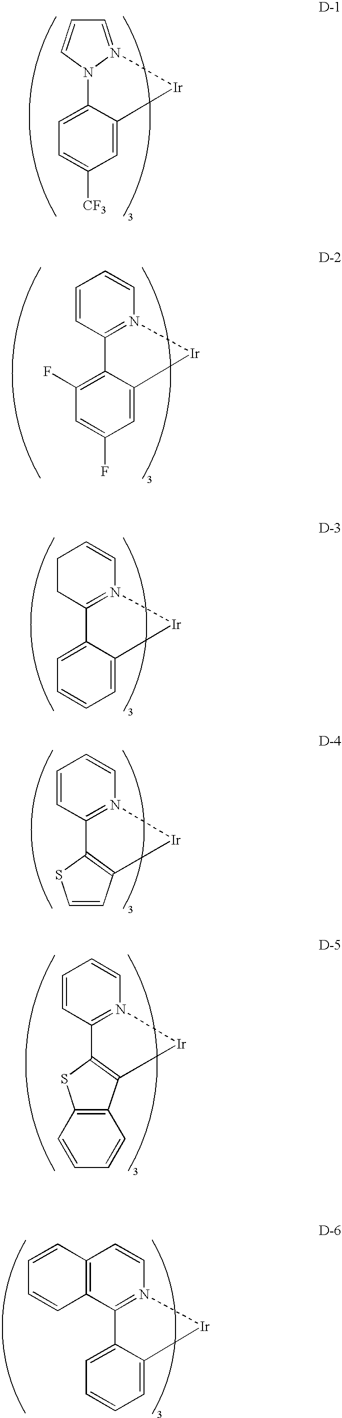

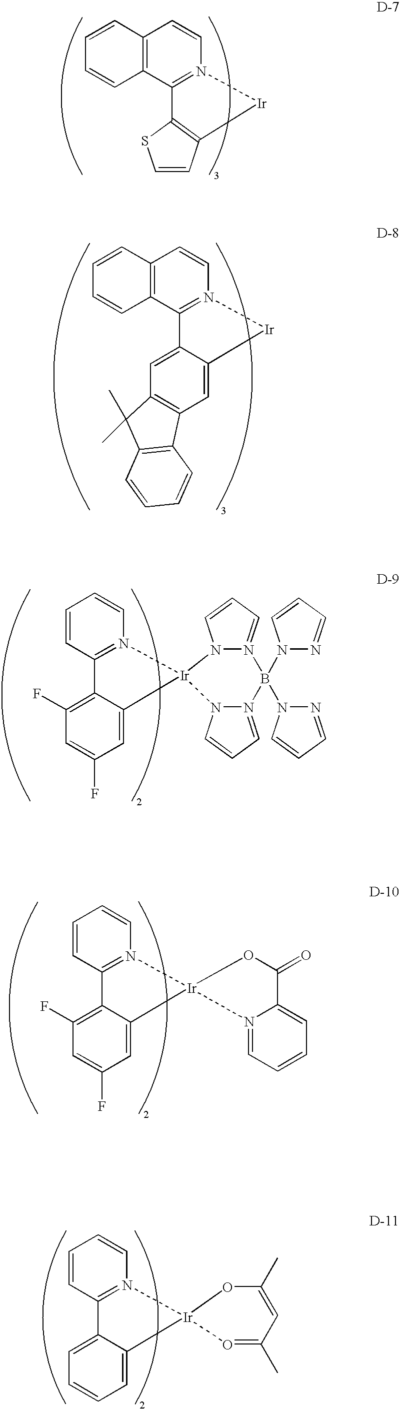

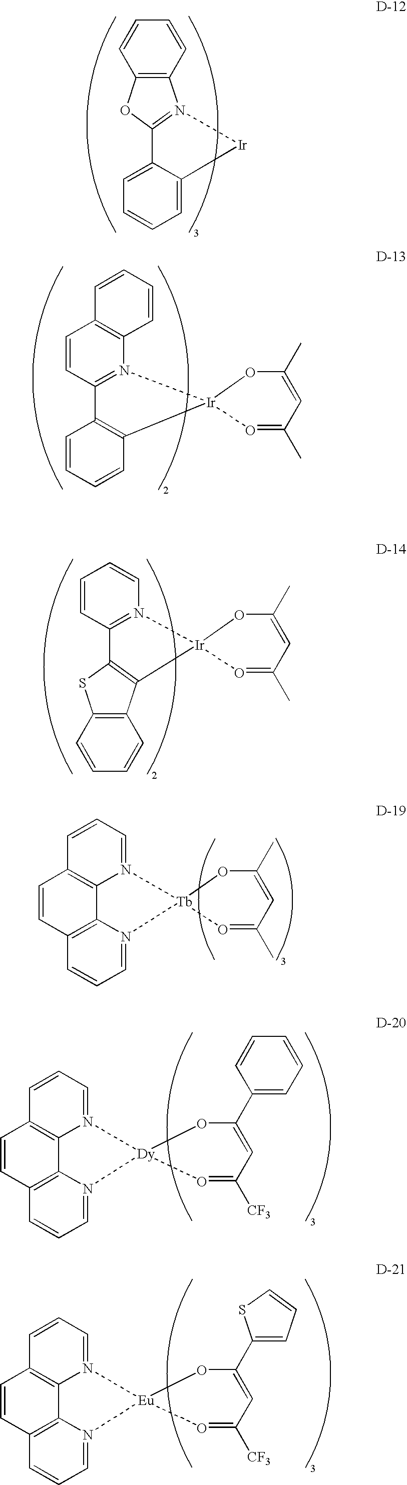

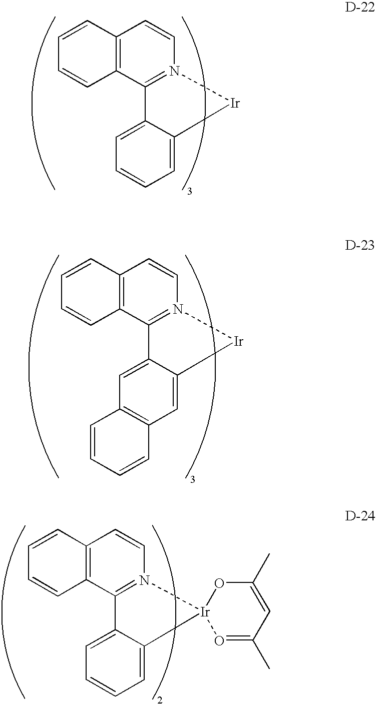

Among these compounds, the phosphorescent materials satisfying the more preferred condition of (2) are D-2, D-3, D-4, D-5, D-6, D-7, D-8, D-9, D-10, D-11, D-12, D-13, D-14, and D-22.

-Host Compound-

As for the host compound used in the luminescent layer, at least two host compounds are used, but these host compounds are not particularly limited as long as the condition of (1) is satisfied. In addition, the host compounds preferably also satisfy the condition of (2).

Regarding the condition of (2), the host compounds more preferably satisfy the relationships 1.2 eV>ΔIp2>0.2 eV and/or 1.2 eV>ΔEa2>0.2 eV, and still more preferably satisfy the relationships 1.2 eV>ΔIp2>0.4 eV and/or 1.2 eV>ΔEa2>0.4 eV

The host compound used for giving Ip(H)min may be a hole transporting host, and the host compound used for giving Ea(H)max may be an electron transporting host.

As the at least two host compounds, hole transporting host compounds having excellent hole transporting properties (hole transporting host) and electron transporting host compounds having excellent electron transporting properties (electron transporting host) may be used.

=Hole Transporting Host=

The hole transporting host in the luminescent layer for use in the present invention may be any known hole transporting material insofar as the condition of (1) is satisfied. The hole transporting host preferably also satisfies the condition of (2). In view of durability and color purity, the ionization potential thereof is preferably from 4.6 to 7.5 eV, more preferably from 5.1 to 7.1 eV, and still more preferably from 5.4 to 7.1 eV

Specific examples of such a hole transporting host include the following materials:
pyrrole, carbazole, triazole, oxazole, oxadiazole, imidazole, polyarylalkane, pyrazoline, pyrazolone, phenylenediamine, arylamine, amino-substituted chalcone, styrylanthracene, fluorenone, hydrazone, stilbene, silazane, aromatic tertiary amine compounds, styrylamine compounds, aromatic dimethylidene-based compounds, porphyrin-based compounds, polysilane-based compounds, poly(N-vinylcarbazole), aniline-based copolymers, thiophene oligomers, electrically conductive high molecular weight oligomers such as polythiophene, organic silanes, carbon films, and derivatives thereof

Among these, preferred as the hole transporting host satisfying the relationships of (2) are carbazole derivatives, aromatic tertiary amine compounds and thiophene derivatives, and more preferred are those having a plurality of carbazole skeletons and/or aromatic tertiary amine skeletons within the molecule.

Specific examples of such a hole transporting host include the following compounds. 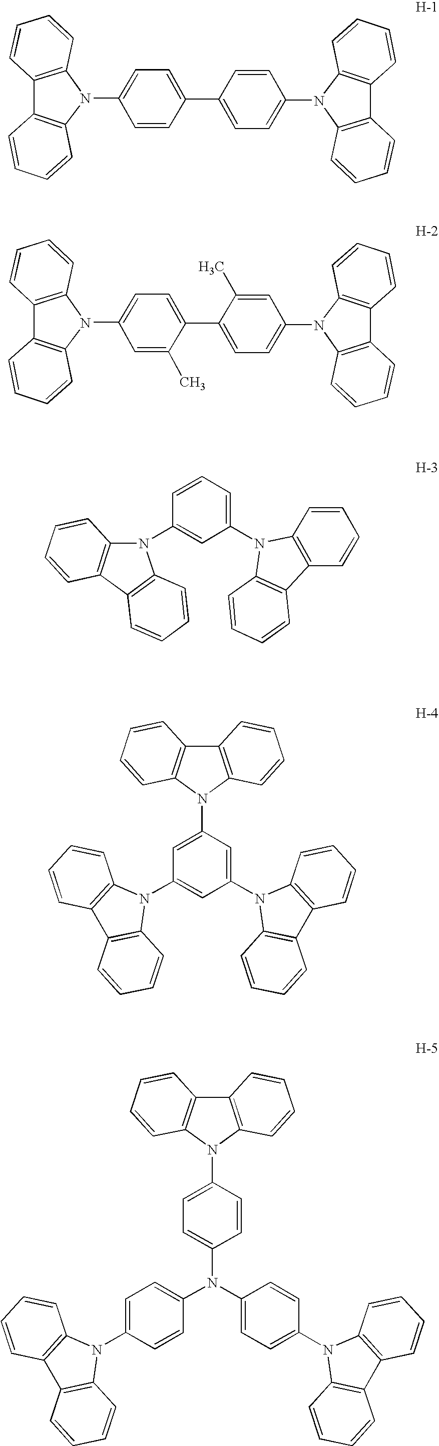 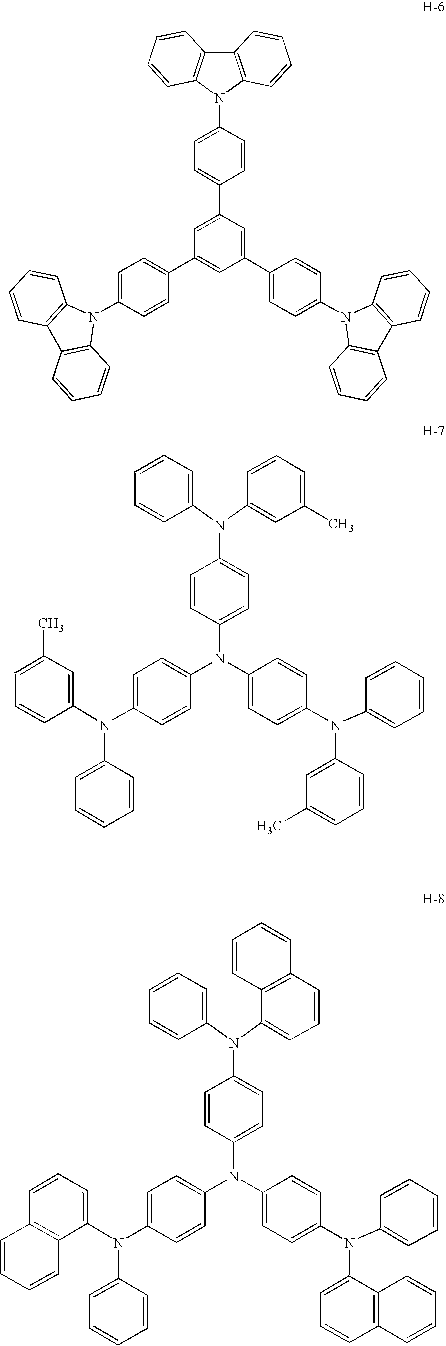 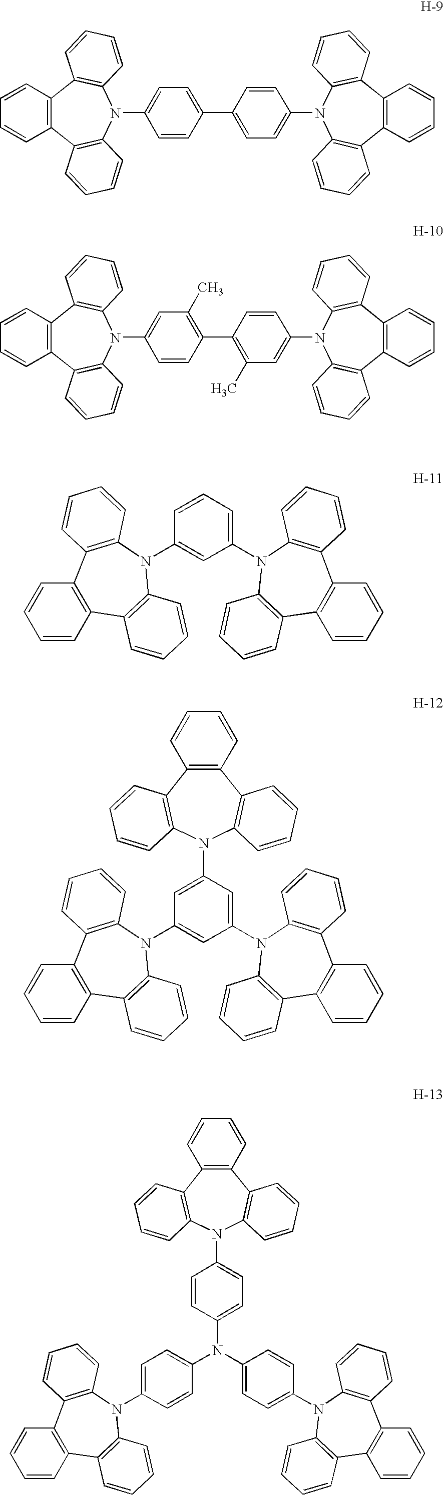 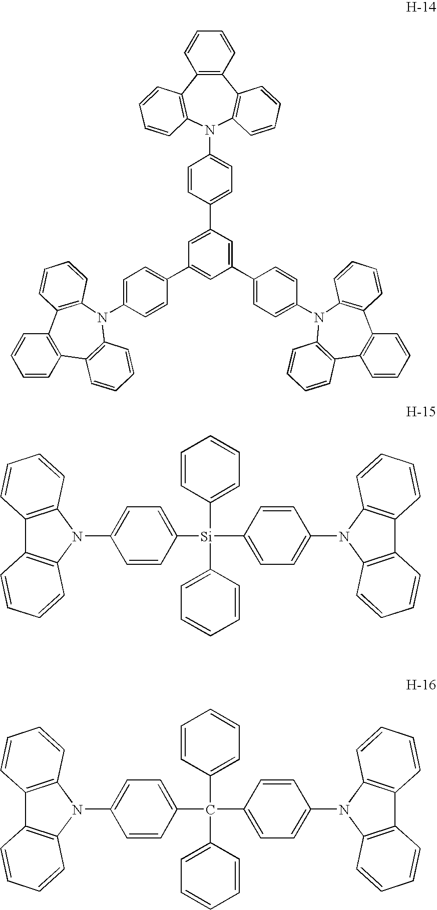
=Transporting Host=

The electron transporting host in the luminescent layer for use in the present invention may be any known electron transporting material insofar as the condition of (1) is satisfied. Further, the electron transporting host preferably also satisfies the condition of (2). In view of durability and color purity, the electron affinity Ea thereof is preferably from 1.2 to 4.0 eV, more preferably from 1.2 to 3.4 eV, still more preferably from 1.2 to 3.0 eV, and yet still more preferably from 1.2 to 2.8 eV

Specific examples the electron transporting host include the following materials: pyridine, pyrimidine, triazine, imidazole, triazole, oxazole, oxadiazole, fluorenone, anthraquinodimethane, anthrone, diphenylquinone, thiopyrandioxide, carbodiimide, fluorenylidenemethane, distyrylpyrazine, fluorine-substituted aromatic compounds, anhydrides or imides of aromatic tetracarboxylic acid (examples of aromatic ring thereof include naphthalene and perylene), anhydrides or imides of aromatic dicarboxylic acid (examples of aromatic ring thereof include benzene and naphthalene), phthalocyanine, derivatives thereof (may form a condensed ring with another ring), and various metal complexes as represented by a metal complex of 8-quinolinol derivative, metal phthalocyanine and a metal complex with the ligand being benzoxazole or benzothiazole Among these electron transporting hosts, metal complexes, azole derivatives (e.g., benzimidazole derivative, imidazopyridine derivative) and azine derivatives (e.g., pyridine derivative, pyrimidine derivative, triazine derivative) are preferred, and in view of durability, metal complex compounds are more preferred in the present invention. The metal complex is a metal complex in which a ligand containing at least one nitrogen atom, oxygen atom or sulfur atom is coordinated to the metal. The metal ion in the metal complex is not particularly limited but is preferably beryllium ion, magnesium ion, aluminum ion, gallium ion, zinc ion, indium ion or tin ion, more preferably beryllium ion, aluminum ion, gallium ion or zinc ion, and still more preferably aluminum ion or zinc ion.

As for the ligand contained in the metal complex, various ligands are known, and examples thereof include the ligands described in H. Yersin, Photochemistry and Photophysics of Coordination Compounds, Springer-Verlag (1987), and Akio Yamamoto, Yuki Kinzoku Kagaku—Kiso to Oyo—(Organic Metal Chemistry—Basics and Applications—), Shokabo (1982), the disclosures of which are incorporated by reference herein.

The ligand is preferably a nitrogen-containing heterocyclic ligand (preferably having from 1 to 30 carbon atoms, more preferably from 2 to 20 carbon atoms, still more preferably from 3 to 15 carbon atoms. This may be a unidentate ligand or a bidentate or higher dentate ligand but is preferably a bidentate ligand and examples thereof include pyridine ligands, bipyridyl ligands, quinolinol ligands and hydroxphenylazole ligands (e.g., hydroxyphenylbenzimidazole ligand, hydroxyphenylbenzoxazole ligand, hydroxyphenylimidazole ligand)), an alkoxy ligand (preferably having from 1 to 30 carbon atoms, more preferably from 1 to 20 carbon atoms, still more preferably from 1 to 10 carbon atoms, such as methoxy, ethoxy, butoxy and 2-ethylhexyloxy), an aryloxy ligand (preferably having from 6 to 30 carbon atoms, more preferably from 6 to 20 carbon atoms, still more preferably from 6 to 12 carbon atom, such as phenyloxy, 1-naphthyloxy, 2-naphthyloxy, 2,4,6-trimethylphenyloxy and 4-biphenyloxy), a heteroaryloxy ligand (preferably having from 1 to 30 carbon atoms, more preferably from 1 to 20 carbon atoms, still more preferably from 1 to 12 carbon atoms, such as pyridyloxy, pyrazyloxy, pyrimidyloxy and quinolyloxy), an alkylthio ligand (preferably having from 1 to 30 carbon atoms, more preferably 1 to 20 carbon atoms, still more preferably from 1 to 12 carbon atoms, such as methylthio and ethylthio), an arylthio ligand (preferably having from 6 to 30 carbon atoms, more preferably 6 to 20 carbon atoms, still more preferably from 6 to 12 carbon atoms, such as phenylthio), a heteroarylthio ligand (preferably having from 1 to 30 carbon atoms, more preferably 1 to 20 carbon atoms, still more preferably from 1 to 12 carbon atoms, such as pyridylthio, 2-benzimidazolylthio, 2-benzoxazoylthio and 2-benzothiazolylthio) or a siloxy ligand (preferably having from 1 to 30 carbon atoms, more preferably from 3 to 25 carbon atoms, still more preferably from 6 to 20 carbon atoms, such as triphenylsiloxy, triethoxysiloxy and triisopropylsiloxy), more preferably a nitrogen-containing heterocyclic ligand, an aryloxy ligand, a heteroaryloxy ligand or a siloxy ligand, still more preferably a nitrogen-containing heterocyclic ligand, an aryloxy ligand or a siloxy ligand.

Specific examples of such an electron transporting host include the following materials.

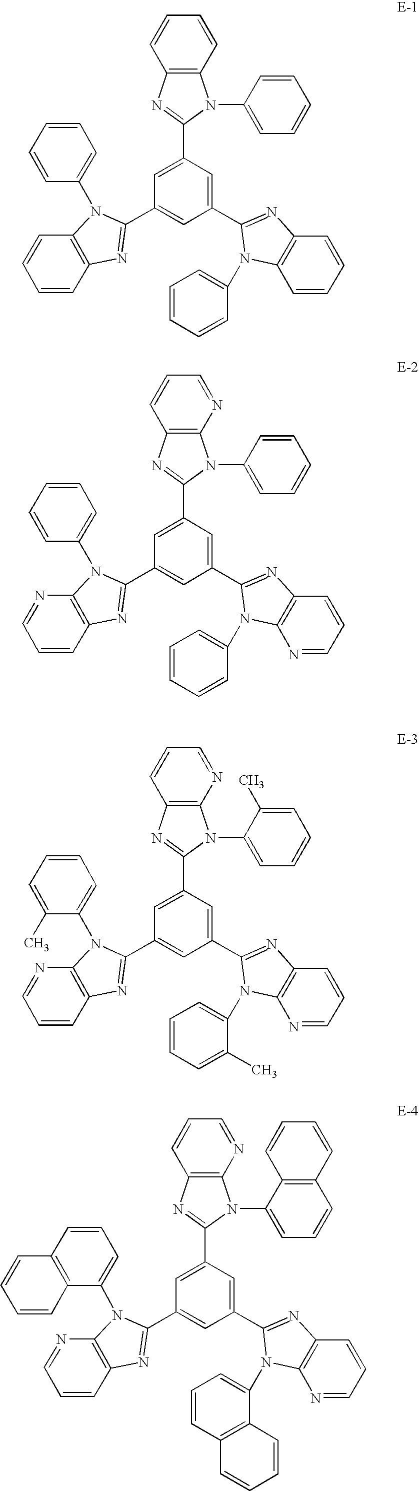

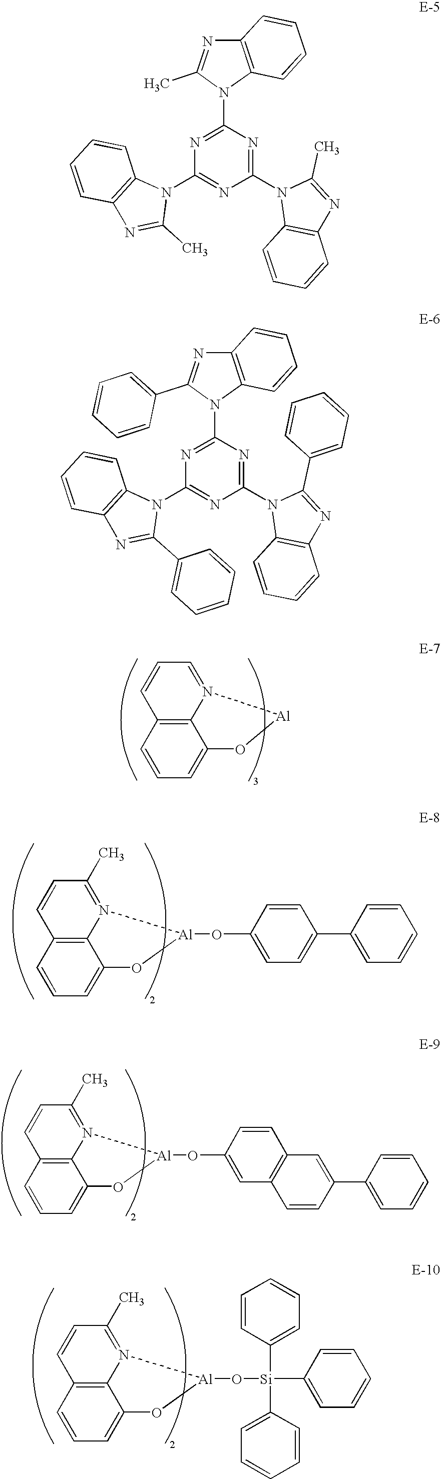

Among these, preferred as the electron transporting host satisfying the condition of (2) are E-1 to E-6, and more preferred is E-3.

In the luminescent layer in the invention, from the viewpoints of the color purity and the luminescence efficiency, the lowest triplet excitation energy, T₁(D1), of the phosphorescent material that satisfies the condition of (1) among the phosphorescent materials contained and the minimum value, T₁(H)min, out of the lowest excitation triplet energies of the at least two host compounds preferably satisfy the relationship of T₁(H)min>T₁(D1).

A value of T₁(D1), when the phosphorescent material satisfies the condition of (1), is determined from the relationship with a host compound. However, from the viewpoint of the, chromaticity T₁(D1) preferably satisfies 1.6 eV<T₁(D1)<3.1 eV and more preferably 1.8 eV<T₁(D1)<3.0 eV

A value of T₁(H)min, as long as the host compound satisfies the condition (1), is not particularly restricted and determined from the relationship with the phosphorescent material. However, from the viewpoint of the driving durability, it preferably satisfies 1.7 eV<T₁(H)min<3.3 eV and more preferably 1.9 eV<T₁(H)min<3.1 eV.

Furthermore, each of contents of a plurality of host compounds according to the invention, though not particularly restricted, from the viewpoint of the driving durability, relative to a mass of the whole compounds constituting the luminescent layer, is preferably 5 to 95% by mass. A more preferable range is 10 to 90% by mass and a further more preferable range is 15 to 85% by mass.

A content ratio of the at least two host compounds in the invention, between two host compounds (a host compound of Ip(H)min: a host compound of Ea(H)max), is preferably 5:95 to 95:5, more preferably 10:90 to 90:10 and particularly preferably 15:85 to 85:15.

The carrier mobility in the luminescent layer may be generally from 10⁻⁷ to 10⁻¹ cm²/Vs and in view of light emission efficiency, preferably from 10⁻⁵ to 10⁻¹ m²/Vs, more preferably from 10⁻⁴ to 10⁻¹ cm²/Vs, and still more preferably from 10⁻³ to 10⁻¹ cm²/Vs.

In view of driving durability, the carrier mobility in the luminescent layer is preferably smaller than the carrier mobility in the carrier transporting layer, which is described below.

As for the carrier mobility, a value obtained by the measurement according to the TOF method (time-of-flight method) is used as the carrier mobility. The TOF method is described in “Hikari Denshi Kinou Yukizairyo Handbook (Photo/Electronic Functional Organic Material Handbook)” edited by Kazuyuki Horie, published by Asakura Shoten (1995), page 287, the disclosure of which is incorporated by reference herein.

The thickness of the luminescent layer is not particularly limited but usually, the thickness is preferably from 1 nm to 500 nm, and in view of light emission efficiency, more preferably from 5 nm to 200 nm, and still more preferably from 10 nm to 100 nm.

(Hole Injecting Layer and Hole Transporting Layer)

The hole injecting layer and the hole transporting layer each have the function of receiving a hole from an anode or an anode side and of transporting the hole to the cathode side.

The hole injecting layer and the hole transporting layer each preferably include, for example, a carbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydrazone derivative, a stilbene derivative, a silazane derivative, an aromatic tertiary amino compound, a styrylamine compound, an aromatic dimethylidyne-based compound, a porphiryn-based compound, an organic silane derivative, carbon, or the like.

The thickness of a hole injecting layer or a hole transporting layer is not particularly limited, but is preferably from 1 nm to 5 μm, more preferably from 5 nm to 1 μm, and still more preferably from 10 nm to 500 nm.

A hole injecting layer or a hole transporting layer may be a single layer structure comprising one kind or two or more kinds of the aforementioned materials, or may also be a multilayer structure comprising a plurality of layers of the same composition or different compositions.

When the carrier transporting layer adjacent to the luminescent layer is a hole transporting layer, in view of driving durability, the Ip(HTL) of the hole transporting layer is preferably smaller than the Ip(D) of the dopant contained in the luminescent layer.

The Ip(HTL) of the hole transporting layer can be measured by the above-described measurement method for the Ip.

From the viewpoint of decreasing the driving voltage of the element, the organic EL element of the invention may contain an electron-accepting dopant in the hole injecting layer or the hole transporting layer. Any material such as an inorganic compound or an organic compound may be used as the electron-accepting dopant contained in the hole-injecting layer or the hole-transporting layer as long as it has electron-accepting properties and is capable of oxidizing organic compounds.

Preferable examples threof among iorganic electron-accepting compounds include Lewis acid compounds such as ferric chloride, aluminum chloride, gallium chloride, indium chloride and antimony pentachloride.

Preferable examples thereof among organic electron-accepting compoudns include compounds having a nitro group, a halogen, a cyano group, a trifluoromethyl group or the like as a substituent thereof, quinone compounds, acid anhydride compounds, and fullerenes.

These electron-accepting dopants may be used singly or in combination of two or more thereof. The amount of the electron-accepting dopant may vary depending on a material thereof. It is preferably in a range of 0.01 to 50% by mass, more preferably in a range of 0.05 to 20% by mass, and still more preferably in a range of 0.1 to 10% by mass, with respect to the materials constituting the hole transporting layer or the hole injecting layer.

The carrier mobility in the hole transporting layer may be generally from 10⁻⁷ to 10⁻¹ cm²/Vs and in view of light emission efficiency, preferably from 10⁻⁵ to 10⁻¹ m²/Vs, more preferably from 10⁻⁴ to 10⁻¹ cm²/Vs, and still more preferably from 10⁻³ to 10⁻¹ cm²/Vs.

As for the carrier mobility, a value measured by the same method as the measurement method for the carrier mobility in the luminescent layer is employed.

Also, in view of driving durability, the carrier mobility in the hole transporting layer is preferably larger than the carrier mobility in the luminescent layer.

(Electron Injecting Layer and Electron Transporting Layer)

The electron injecting layer and the electron transporting layer are each a layer having any one function of receiving an electron from the cathode, transporting an electron, or blocking a hole which is injectable from the anode.

Specific examples of the material for the electron injecting layer and the electron transporting layer include pyridine, pyrimidine, triazine, imidazole, triazole, oxazole, oxadiazole, fluorenone, anthraquinodimethane, anthrone, diphenylquinone, thiopyrandioxide, carbodiimide, fluorenylidenemethane, distyrylpyrazine, fluorine-substituted aromatic compounds, anhydrides or imides of aromatic tetracarboxylic acid (examples of aromatic ring thereof include naphthalene and perylene), anhydrides or imides of aromatic dicarboxylic acid (examples of aromatic ring thereof include benzene and naphthalene), phthalocyanine, derivatives thereof (may form a condensed ring with another ring), and various metal complexes as represented by a metal complex of 8-quinolinol derivative, metal phthalocyanine and a metal complex with the ligand being benzoxazole or benzothiazole.

The electron injecting layer and the electron transporting layer are not particularly limited in their thickness but usually, from the standpoint of decreasing the driving voltage, the thickness is preferably from 1 nm to 5 μm, more preferably from 5 nm to 1 μm, and still more preferably from 10 nm to 500 nm.

The electron injecting layer and the electron transporting layer each may have a single-layer structure comprising one kind or two or more kinds of the above-described materials or may have a multilayer structure comprising a plurality of layers having the same composition or differing in composition.

When the carrier transporting layer adjacent to the luminescent layer is an electron transporting layer, in view of driving durability, the Ea(ETL) of the electron transporting layer is preferably larger than the Ea(D) of the dopant contained in the luminescent layer.

As for the Ea(ETL), a value measured by the same method as the above-described measurement method for the Ea is employed.

From the viewpoint of decreasing the driving voltage of the element, the organic EL element of the invention may contain an electron-donating dopant in the electron injecting layer or the electron transporting layer. Any materials may be used as the electron-donating dopant contained in the electron-injecting layer or the electron-transporting layer as long as it has electron-donating properties and is capable of reducing organic compounds. Preferable examples of the electron-donating dopants include alkali metals such as Li, alkaline earth metals such as Mg, transition metals including rare earth metals, and reductive organic compounds. Metals having a work function of 4.2 eV or less may be preferably used. Specific examples thereof include Li, Na, K, Be, Mg, Ca, Sr, Ba, Y, Cs, La, Sm, Gd and Yb. Specific examples of the reductive organic compounds include nitrogen-containing compounds, sulfur-containing compounds and phosphorus-containing compounds.

These electron-donating dopants may be used singly or in combination of two or more thereof The amount of the electron-donating dopant may vary depending on a material thereof It is preferably in a range of 0.1 to 99% by mass, more preferably in a range of 1.0 to 80% by mass, and still more preferably in a range of 2.0 to 70% by mass, with respect to the materials constituting the electron transporting layer or the electron injecting layer.

The carrier mobility in the electron transporting layer may be generally from 10⁻⁷ to 10⁻¹ cm²/Vs and in view of light emission efficiency, preferably from 10⁻⁵ to 10⁻¹ m²/Vs, more preferably from 10⁻⁴ to 10⁻¹ cm²/Vs, and still more preferably from 10⁻³ to 10⁻¹ cm²/Vs.

Also, in view of driving durability, the carrier mobility in the electron transporting layer is preferably larger than the carrier mobility in the luminescent layer. The carrier mobility here is measured by the same method as that for the carrier mobility in the hole transporting layer.

With respect to the carrier mobility of the luminescent element of the present invention, in view of driving durability, the carrier mobility among the hole transporting layer, the electron transporting layer and the luminescent layer is preferably (electron transporting layer≧hole transporting layer)>luminescent layer.

(Hole Blocking Layer)

The hole blocking layer is a layer having a function of preventing a hole which is transported from the anode side to the luminescent layer, from passing through to the cathode side. In the present invention, the hole blocking layer can be provided as an organic compound layer adjacent to the luminescent layer on the cathode side.

The hole blocking layer is not particularly limited but specifically, may comprise an aluminum complex (e.g., BAlq), a triazole derivative, a pyrazabole derivative or the like.

In order to decrease the driving voltage, the thickness of the hole blocking layer in general is preferably 50 nm or less, more preferably from 1 to 50 nm, and still more preferably from 5 to 40 nm.

(Anode)

The anode may usually serve as an electrode that supplies holes to the organic compound layer. The shape, structure, size and the like of the anode are not particularly limited and can be selected as appropriate from well known electrode materials depending on the applications and purposes of a luminescent element. As mentioned supra, the anode is usually formed as a transparent anode.

Examples of the material of the anode that are suitable include metals, alloys, metal oxides, electric conductive organic compounds and mixtures thereof, which preferably have a work function of 4.0 eV or more. Specific examples the material of the anode include electric conductive metal oxides such as tin oxides doped with antimony or fluorine (ATO, FTO), tin oxide, zinc oxide, indium oxide, indium tin oxide (ITO), and indium zinc oxide (IZO); metals such as gold, silver, chromium, and nickel; mixtures or laminates of these metals and electric conductive metal oxides; electric conductive inorganic substances such as copper iodide and copper sulfate; electric conductive organic materials such as polyaniline, polythiophene, and polypyrrole; laminates and the like of these and ITO. Among them, the material of the anode is preferably an electric conductive metal oxide, and more preferably ITO from the viewpoint of productivity, high electric conductivity, transparency and the like.

An anode can be formed on the above-described substrate in accordance with a method selected, as appropriate, in consideration of its suitability to the materials constituting the above-described anode, from wet methods such as the printing method and the coating method, physical methods such as the vacuum deposition method, the sputtering method and the ion plating method, chemical methods such as CVD and the plasma CVD method, and the like. For instance, when ITO is selected as the material of the anode, the formation of the anode can be carried out according to the direct current or high-frequency sputtering method, the vacuum deposition method, the ion plating method or the like.

In the organic electroluminescent element of the invention, the position of the anode to be formed is not particularly limited and can be selected as necessary depending on the applications or purposes of the luminescent element. The anode may be formed on the entire surface of one surface of the substrate, or may also be formed on a portion thereof.

The patterning for forming the anode may be carried out by chemical etching such as photolithography, or may also be carried out by physical etching such as by means of a laser, or may also be carried out by vacuum deposition or sputtering after placing a mask, or may also be carried out by the lift-off method or the printing method.

The thickness of the anode can be selected, as appropriate, depending on the material constituting the above-described anode, cannot be specified unconditionally, may be usually from 10 nm to 50 μm, and is preferably from 50 nm to 20 μm.

The resistance value of the anode is preferably 10³ Ω/sq or less, and more preferably 10² Ω/sq or less. When the anode is a transparent anode, the anode may be colorless transparent or may also be colored transparent. For the extraction of light emission from the anode side, the transmittance is preferably 60% or more, and more preferably 70% or more.

Additionally, transparent anodes which can be applied to the present invention are described in detail in “Tohmeidodenmaku No Shintenkai (Developments of Transparent Conductive Films)” supervised by Yutaka Sawada, published by CMC (1999), the disclosure of which is incorporated by reference herein. When a plastic substrate of low heat resistance is used, it is preferable to employ ITO or IZO and form a transparent anode at a low temperature of 150° C. or less.

(Cathode)

The cathode may usually serve as an electrode that injects an electron to an organic compound layer. The shape, structure, size and the like are not particularly limited and can be selected as appropriate from well known electrode materials depending on the applications and purposes of a luminescent element.

Examples of the material of the cathode include metals, alloys, metal oxides, electric conductive compounds and mixtures thereof, and preferably have a work function of 4.5 eV or less. Specific examples include alkali metals (e.g., Li, Na, K, Cs and the like), alkali earth metals (e.g., Mg, Ca, and the like), gold, silver, lead, aluminum, sodium-potassium alloy, lithium-aluminum alloy, magnesium-silver alloy, indium, rare earth metals such as ytterbium, and the like. These may be used singly and can be used in combination of two or more kinds from the standpoint of compatibility between stability and electron injection properties.

Among them, preferable examples of the material of the cathode include alkali metals and alkali earth metals in terms of electron injection properties and include materials primarily made of aluminum in terms of excellent shelf life.

A material primarily made of aluminum as used herein means aluminum alone, or an alloy of aluminum and a 0.01 to 10% by mass alkali metal or alkali earth metal or a mixture thereof (e.g., lithium-aluminum alloy, magnesium-aluminum alloy, and the like).

In addition, materials of the cathode are described in JP-A Nos. 2-15595 and 5-121172, the disclosures of which are incorporated by reference herein, and the materials described in these gazettes can also be applied to the invention.

Methods of forming the cathode are not particularly limited and can be carried out in accordance with well known methods. For instance, a cathode can be formed in accordance with a method selected, as appropriate, in consideration of its suitability to the materials constituting the above-described cathode, from wet methods such as the printing method and the coating method; physical methods such as the vacuum deposition method, the sputtering method and the ion plating method; chemical methods such as CVD and the plasma CVD method; and the like. For example, when metals and the like are selected as materials of the cathode, the formation can be carried out with one kind thereof or two or more kinds thereof at the same time or one by one in accordance with the sputtering method or the like.

The patterning for forming the cathode may be carried out by chemical etching such as photolithography, or may also be carried out by physical etching such as by means of a laser, or may also be carried out by vacuum deposition or sputtering after placing a mask, or may also be carried out by the lift-off method or the printing method.

In the invention, the position of a cathode to be formed is not particularly limited and may be formed on the entire organic compound layer, or may be formed on a portion thereof

Also, a dielectric layer with a thickness of 0.1 nm to 5 nm made of a fluoride or an oxide of an alkali metal or an alkali earth metal, or the like, may be inserted between the cathode and the organic compound layer. This dielectric layer can be considered to be a kind of electron injecting layer. The dielectric layer can be formed by, for example, the vacuum deposition method, the sputtering method, the ion plating method or the like.

The thickness of a cathode can be selected, as appropriate, depending on the material constituting the above-described cathode, cannot be specified unconditionally, may be normally from 10 nm to 5 μm, and is preferably from 50 nm to 1 μm.

The cathode may be transparent or may be opaque. A transparent cathode can be formed by a process that involves thinly film-forming the material constituting the above-described cathode to a thickness of from 1 to 10 nm, and then laminating thereon a transparent, electric conductive material of the aforementioned ITO, IZO, or the like.

(Substrate)

In the invention a substrate can be used. The substrate to be used in the invention is preferably a substrate that does not scatter or attenuate light emitted from an organic compound layer. Specific examples of the substrate include inorganic materials such as Yttria-stabilized Zirconia (YSZ) and glass; polyesters such as polyethylene terephthalate, polybutylene phthalate, and polyethylene naphthalate; and organic materials such as polystyrene, polycarbonate, polyether sulfone, polyallylate, polyimides, polycycloolefins, norbornene resin, and poly(chlorotrifluoroethylene).

When the substrate is made of glass, the glass is preferably no-alkali glass in order to reduce ions deriving from the glass. When the substrate is made of soda lime glass, the substrate is preferably coated with a barrier coating such as silica. When an organic material is used, the material is preferably excellent in heat resistance, dimension stability, solvent resistance, electric insulation and processability.

The shape, structure, size and the like of a substrate are not particularly limited and can be selected as appropriate depending on the applications, purposes and the like of a luminescent element. In general, the shape is preferably board-shaped. The structure of the substrate may be a single-layer structure or may also be a laminated structure. The substrate may be fabricated with a single member or may also be formed with two or more members.

The substrate may be colorless transparent or may also be colored transparent, and is preferably colorless transparent in terms of no scattering or attenuation of the light emitted from the luminescent layer.

A moisture penetration resistance layer (gas barrier layer) can be formed on the surface or the back of the substrate.

Materials for the moisture penetration resistance layer (gas barrier layer) that are suitably used include inorganic substances such as silicon nitrate and silicon oxide. The moisture penetration resistance layer (gas barrier layer) can be formed by, for example, the radio-frequency (high-frequency) sputtering process or the like.

When a thermoplastic substrate is used, a hard coat layer or an undercoat layer may be further formed as required.

(Protective Layer)

In the invention, the whole organic EL element may be protected by a protective layer.

Any material may be contained in the protective layer insofar as it has the ability to prevent the intrusion of materials, such as water and oxygen, which promote the deterioration of the element, into the element.

Specific examples of the material of the protective layer include metals such as In, Sn, Pb, Au, Cu, Ag, Al, Ti and Ni; metal oxides such as MgO, SiO, SiO₂, Al₂O₃, GeO, NiO, CaO, BaO, Fe₂O₃, Y₂O₃, and TiO₂; metal nitrates such as SiNx and SiNxOy; metal fluorides such as MgF₂, LiF, AlF₃ and CaF₂; polyethylene, polypropylene, polymethylmethacrylate, a polyimide, polyurea, polytetrafluoroethylene, polychlorotrifluoroethylene, polydichlorodifluoroethylene and copolymers of chlorotrifluoroethylene and dichlorodifluoroethylene; copolymers obtained by copolymerization of a monomer mixture including tetrafluoroethylene and at least one kind of comonomer; fluorine-containing copolymers having a ring structure on the copolymer backbone thereof; water absorptive materials having a water absorption of 1% or more; moisture-proof materials having a water absorption of 0.1% or less; and the like.

A process of forming the protective layer is not particularly limited. Examples of a method that can be used include a vacuum deposition process, a sputtering process, a reactive sputtering process, a MBE (molecular beam epitaxy) process, a cluster ion beam process, a ion plating process, a plasma polymerization process (the high-frequency excited ion plating process), a plasma CVD process, a laser CVD process, a thermal CVD process, a gas source CVD process, a coating process, a printing process, and a transfer process.

(Sealing)

Furthermore, in the organic electroluminescent element of the invention, the entire element may be sealed with a sealing container.

Also, the space between the sealing container and the luminescent element may be filled with a moisture absorbent or an inert liquid. The moisture absorbent is not particularly limited. Specific examples of the moisture absorbent include barium oxide, sodium oxide, potassium oxide, calcium oxide, sodium sulfate, calcium sulfate, magnesium sulfate, phosphorus pentaoxide, calcium chloride, magnesium chloride, copper chloride, cesium fluoride, niobium fluoride, calcium bromide, vanadium bromide, a molecular sieve, zeolite, magnesium oxide, and the like. An inert liquid is not particularly limited and the examples include paraffins, liquid paraffins, fluorine-based solvents such as perfluoroalkanes, perfluoroamines and perfluoroethers, chlorine-based solvents, and silicone oils.

In the organic electroluminescent element of the present invention, a DC (which, if desired, may contain an AC component) voltage (usually from 2 to 15 V) or a DC current is applied between the anode and the cathode, whereby light emission can be obtained.

An important characteristic value of the organic electroluminescent element is its external quantum efficiency. The external quantum efficiency is calculated according to “external quantum efficiency φ=number of photons released from element/number of electrons injected to element”. The larger this value, the more advantageous the element in view of electric power consumption.

The external quantum efficiency of the element is preferably 6% or more, and more preferably 12% or more, because reduction in the power consumption and elevation of the driving durability can thus be realized.

As for the numerical value of the external quantum efficiency, a maximum value of external quantum efficiency when the element is driven at 20° C., or a value of external quantum efficiency in the vicinity of 100 to 300 cd/m² (preferably 200 cd/m²) when the element is driven at 20° C., can be used.

The external quantum efficiency of the luminescent element can also be calculated from the measured values of light emission brightness, light emission spectrum and current density, and the relative luminosity curve. More specifically, the number of electrons input can be calculated by using the current density value. Then, the light emission brightness can be converted into the number of photons which are emitted as light by integral computation using the light emission spectrum and relative luminosity curve (spectrum), and from the values obtained, the external quantum efficiency (%) can be calculated according to “(number of photons which are emitted as light/number of electrons input into element)×100”.

In the present invention, the external quantum efficiency obtained as follows may be used: a constant DC voltage is applied to an EL element to cause light emission by using Source Measure Unit Model 2400 manufactured by Toyo Corporation, the brightness is measured by using a spectrophotometer (brightness meter) SR-3 manufactured by Topcon Corporation, the external quantum efficiency at 200 cd/m² is calculated, and the value obtained is used.

The driving of an organic electroluminescent element of the invention can utilize methods described in, for example, JP-A Nos. 2-148687, 6-301355, 5-29080, 7-134558, 8-234685 and 8-241047, Japanese Patent No. 2784615, and U.S. Pat. Nos. 5,828,429 and 6,023,308, the disclosures of which are incorporated by reference herein.

The organic EL element of the invention can be suitably used in the fields of display devices, displays, backlights, electrophotography, light sources for illumination, light sources for recording, light sources for exposure, light sources for reading, signs, sign boards, interiors, optical communications, and the like.

### EXAMPLES

In what follows, with reference to examples, the invention will be specifically described. However, the invention is not restricted thereto.

### Example 1

To one where on a glass substrate an indium/tin oxide (ITO) transparent conductive film was deposited by 150 nm (manufactured by Geomatic Co., Ltd.), by use of photolithography and hydrochloric acid etching, the patterning was applied and thereby a anode was formed. The patterned ITO substrate, after washing in an order of ultrasonic washing with acetone, water washing with pure water and ultrasonic washing with isopropyl alcohol, was dried under nitrogen blow, finally followed by UV ozone cleaning, and was disposed in a vacuum deposition unit. Thereafter, the vacuum deposition unit was evacuated to a degree of vacuum of 2.7×10⁻⁴ Pa or less.

Subsequently, in the deposition unit, copper phthalocyanine (CuPc) shown below was heated and deposited at a deposition speed of 0.1 nm/sec, and thereby a hole injecting layer having a film thickness of 10 nm was formed.

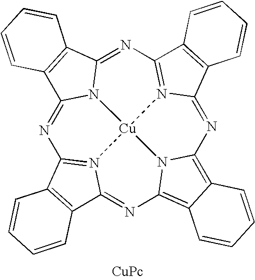

In the next place, on the hole injecting layer formed according to the above, 4,4′-bis[N-(1-naphtyl)-N-phenylamino]biphenyl (α-NPD) shown below is heated with a heater and deposited at a deposition speed of 0.2 nm/sec, and thereby a hole transporting layer having a film thickness of 60 nm was formed.

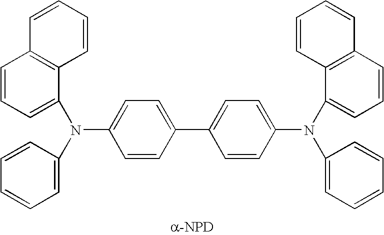

Then, on the hole transporting layer formed as mentioned above, as the host materials (host compounds) contained in a luminescent layer, a mixture (75:25 by weight ratio) of 4,4′-N,N′-dicarbazole-biphenyl (CBP) and an electron transporting host 1 shown below, and as phosphorescent organic metal complexes as the dopant materials (phosphorescent materials), tris(2-phenylpyridine)iridium (dopant A) shown below and a platinum complex (dopant B) shown below were heated, and a luminescent layer was formed by use of a ternary simultaneous vacuum deposition method. A deposition speed of CBP was controlled to 0.2 nm/sec and thereby a luminescent layer that contains 5% by mass of the dopant A and 5% by mass of the dopant B was laminated with a film thickness of 30 nm on the hole transporting layer.

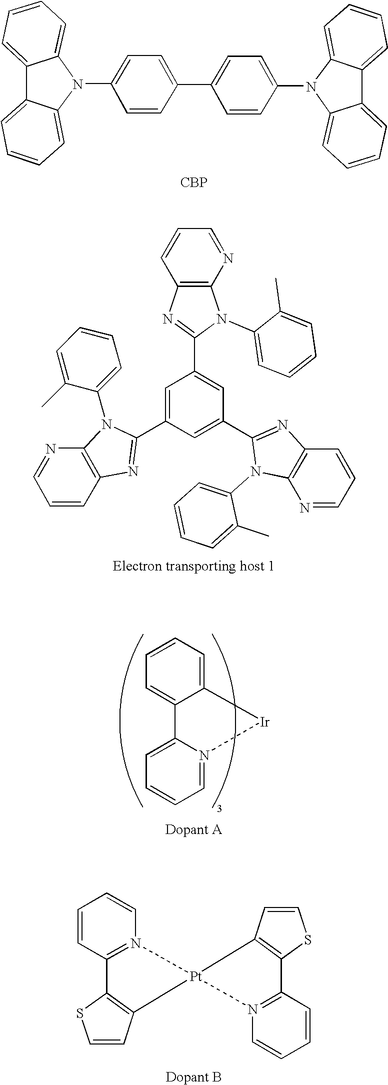

Furthermore, a compound (hole blocking material C) shown below was deposited at the deposition speed of 0.1 nm/sec and thereby a hole blocking layer having a film thickness of 10 nm was laminated on the luminescent layer.

The ionization potential of the hole blocking material C measured by use of AC-1 (manufactured by Riken Keiki Co., Ltd.) was 5.8.
Hole Blocking Material C

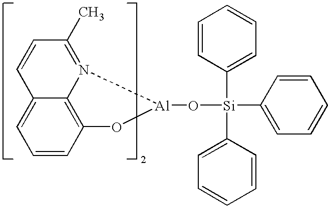

Further subsequently, on the hole blocking layer, tris(8-hydroxyquinolinolate)aluminum (Alq) shown below was deposited at the deposition speed of 0.2 nm/sec, and thereby an electron transporting layer having a film thickness of 35 nm was formed.

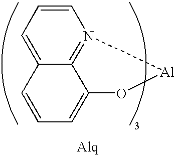

Thereafter, lithium fluoride (LiF) was deposited on the electron transporting layer at the deposition speed of 0.1 nm/sec and with a film thickness of 1.5 nm to form an electron injecting layer, and furthermore aluminum was deposited at the deposition speed of 0.5 nm/sec to form a cathode having a film thickness of 100 nm.

An aluminum lead wire was connected to each of the anode and the cathode

Thus, an organic EL element according to example 1 was obtained.

At the time of deposition, in order to be able to obtain a desired film thickness, a quartz oscillator type film forming controller (trade name: CRTM6000, manufactured by ULVAC Inc.) was used to monitor.

To thus obtained organic EL element, by use of a source measure unit (trade name: MODEL 2400, manufactured by Keithley Instrument Inc.), a direct current voltage was applied, followed by measuring the spectral radiation brightness with a brightness meter (trade name: SR-3, manufactured by TOPCON Corp.).

From the measurements, external quantum efficiencies and values of peak emission wavelengths were obtained.

The maximum wavelength of a light emission spectrum of the element obtained according to example 1 was 584 nm and identified to be derived from the dopant B.

Furthermore, the durability was evaluated under the conditions of the initial brightness of 200 cd/m² and a constant current drive and a time until the brightness became 100 cd/m² was measured. Results are shown in Table 1.

### Example 2

An organic EL element was prepared and measured in the same manner as in example 1, except that a mixture (75:25 by weight ratio) of a hole transporting host 3 below and an electron transporting host 2 below was used as the host materials contained in a luminescent layer.

The maximum wavelength of a light emission spectrum of the element obtained according to example 2 was 584 nm and identified to be derived from the dopant B.
Electron Transporting Host 2

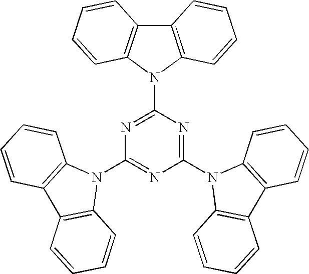

### Comparative Example 1

An organic EL element was prepared and measured in the same manner as in example 1, except that the dopant B alone was used as the dopant contained in the luminescent layer.

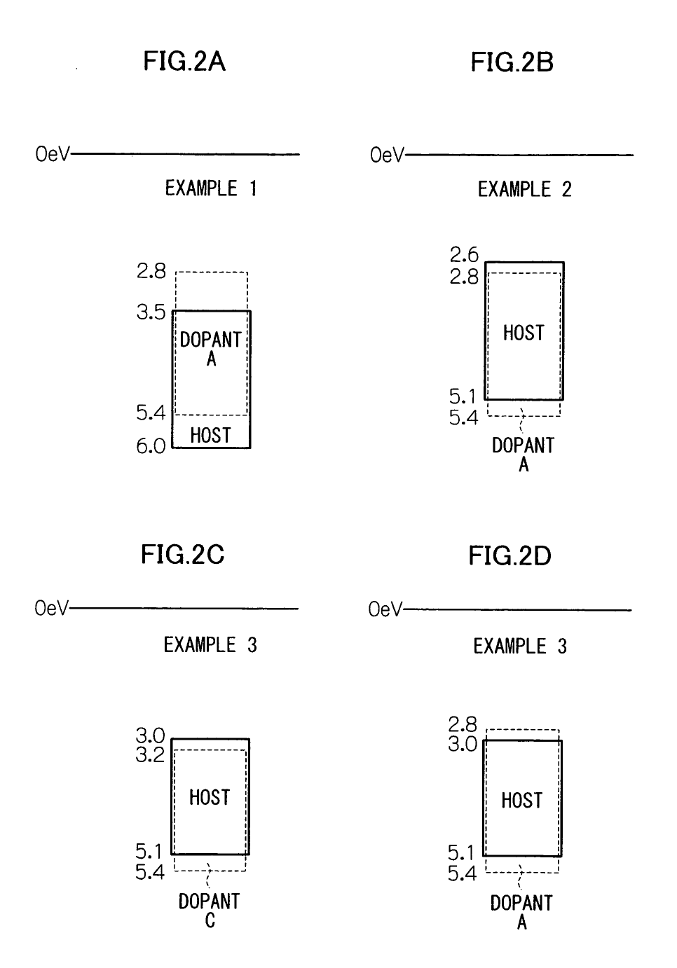

Measurements of examples 1 and 2 and comparative example 1 are shown in Table 1. Energy states of examples 1 and 2 are shown in FIG. 2A and FIG. 2B.

TABLE 1

| | | | Comparative |
|---|---|---|---|
| | Example 1 | Example 2 | example 1 |
| Phosphorescent | A, B | A, B | B |
| material | | | |
| Host material | CBP:Electron | Hole transporting host 3:Electron | CBP:Electron |
| | transporting host 1 | transporting host | transporting host 1 |
| | (75:25) | 2 (75:25) | (75:25) |
| Ip(D1) (eV) | 5.4 (dopant A) | 5.4 (dopant A) | |
| Ip(H)min (eV) | 6 | 5.1 | |
| ΔIp1: Ip(D1) − Ip(H)min | −0.6 | 0.3 | |
| Ea(D1) (eV) | 2.8 | 2.8 | |
| Ea(H)max (eV) | 3.5 | 2.6 | |
| ΔEa1: | 0.7 | −0.2 | |
| Ea(H)max − Ea(D1) | | | |
| T₁(D1) | 2.52 | 2.52 | |
| T₁(H)min | 2.56 | 2.60 | |
| Peak | 584 | 584 | 584, 490 |
| wavelength | | | |
| (nm) | | | |
| External | 8.2 | 6.5 | 3.1 |
| quantum | | | |
| efficiency (%) | | | |
| Durability (Hr) | 2800 | 1800 | 900 |

As shown in Table 1, it was found that the elements according to examples 1 and 2 were high in the external quantum efficiency and excellent in the durability.

Furthermore, it was also found that the element according to comparative example 1 where the luminescent layer contains only dopant B, because of exhibiting two luminescent peaks, is poor in the color purity, and, when at least both of two dopants are doped in the luminescent layer like in the element according to example 1, the luminescent peaks become one to improve the color purity, and high luminescent intensity and driving durability can be obtained.

When devices are prepared in the same manner as in examples 1 and 2 except that the mixing ratio of the host materials is in the range of 30:70 to 75:25, favorable results can be obtained. Favorable results can also be obtained when each of dopant A and dopant B has a concentration of 1 to 10% by mass.

### Example 3

An organic electroluminescent element was prepared in the same manner as in example 1, except that, as the host materials contained in a luminescent layer, a mixture (75:25 by weight ratio) of a hole transporting host 3 and an electron transporting host 3 shown below, and as phosphorescent organic metal complexes as the dopant materials, the tris(2-phenylpyridine)iridium (dopant A) and an iridium complex (dopant C) below were heated, and a luminescent layer was formed by use of a ternary simultaneous vapor deposition method. Relationships between the ionization potentials and the electron affinities of the phosphorescent materials and the host materials are shown in Table 2. Furthermore, energy states of example 3 are shown in FIGS. 2C and 2D.

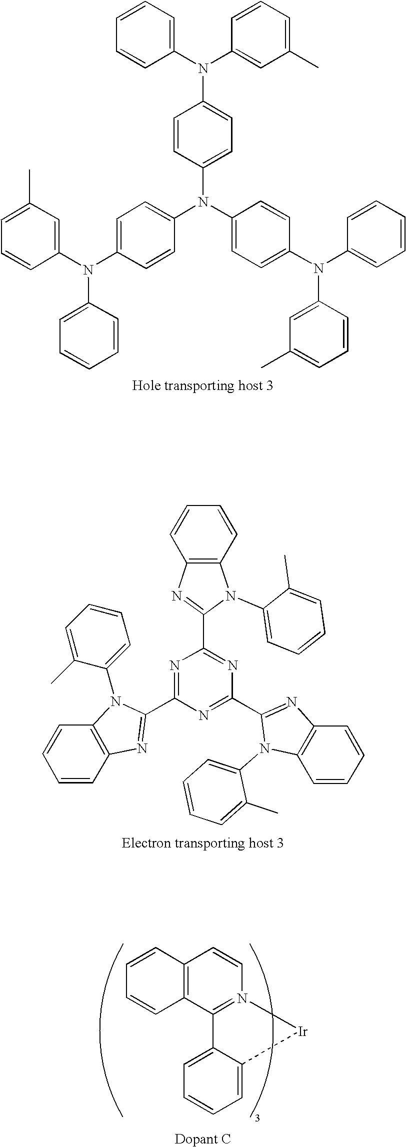

TABLE 2

| Phosphorescent material | C | Phosphorescent material | A |
|---|---|---|---|
| Host material (mixing | Hole transporting host | | |
| ratio) | 3:Electron transporting host 3 (75:25) | | |
| Ip(D1) (eV) | 5.4 | Ip(D2) (eV) | 5.4 |
| Ip(H)min (eV) | 5.1 | Ip(H)min (eV) | 5.1 |
| ΔIp1: Ip(D1) − Ip(H)min | 0.3 | ΔIp2: Ip(D2) − Ip(H)min | 0.3 |
| Ea(D1) (eV) | 3.2 | Ea(D2) (eV) | 2.8 |
| Ea(H)max (eV) | 3.0 | Ea(H)max (eV) | 3.0 |
| ΔEa1: Ea(H)max − Ea(D1) | −0.2 | ΔEa2: Ea(H)max − Ea(D2) | 0.2 |

| | |
|---|---|
| T₁(D1) | 2.07 |
| T₁(H)min | 2.60 |
| Peak wavelength (nm) | 625 |
| External quantum | 5.6% |
| efficiency (%) | |

The element according to example 3 was measured and evaluated as well in the same manner as in example 1. It was found that the element according to example 3 is excellent in the luminescent efficiency.

When a device is prepared in the same manner as in example 3 expect that the mixing ratio of the host materials is in the range of 30:70 to 75:25, favorable results can be obtained. Favorable results can also be obtained when each of dopant A and dopant B has a concentration of 1 to 10% by mass.

According to the invention, an organic electroluminescent element excellent in the driving durability and the luminescent efficiency can be obtained.

What is claimed is:

1. An organic electroluminescent element comprising one or more organic compound layers between an anode and a cathode, wherein the one or more organic compound layers include at least one luminescent layer, the luminescent layer comprises at least two host compounds and at least two phosphorescent materials, and the at least two phosphorescent materials include a phosphorescent material (D1) that satisfies at least one of the following conditions:
(a) when the ionization potential of the phosphorescent material (D1) is defined as Ip(D1) and the minimum value out of the ionization potentials of the at least two host compounds is defined as Ip(H)min, ΔIp1 as defined by ΔIp1=Ip(D1)−Ip(H)min satisfies a relationship of ΔIp1<0 eV, and
(b) when the electron affinity of the phosphorescent material (D1) is defined as Ea(D1) and the maximum value out of the electron affinities of the at least two host compounds is defined as Ea(H)max, ΔEa1 as defined by ΔEa1=Ea(H)max−Ea(D1) satisfies a relationship of ΔEa1<0 eV.

2. The organic electroluminescent element of claim 1, wherein the at least two phosphorescent materials include a phosphorescent material (D2) that satisfies the following conditions:
(c) when the ionization potential of the phosphorescent material (D2) is defined as Ip(D2) and the minimum value out of the ionization potentials of the at least two host compounds is defined as Ip(H)min, ΔIp2 as defined by ΔIp2=Ip(D2)−Ip(H)min satisfies a relationship of ΔIp2>0 eV, and
(d) when the electron affinity of the phosphorescent material (D2) is defined as Ea(D2) and the maximum value out of the electron affinities of the at least two host compounds is defined as Ea(H)max, ΔEa2 as defined by ΔEa2=Ea(H)max−Ea(D2) satisfies a relationship of ΔEa2>0 eV.

3. The organic electroluminescent element of claim 1, wherein when the minimum value out of the lowest triplet excitation energies of the at least two host materials is defined as T₁(H)min, the T₁(H)min and the lowest excitation triplet energy T₁(D1) of the phosphorescent material (D1) satisfy the relationship of T₁(H)min>T₁(D1).

4. The organic electroluminescent element of claim 3, wherein a relationship of 1.6 eV<T₁(D1)<3.1 eV is satisfied.

5. The organic electroluminescent element of claim 3, wherein a relationship of 1.7 eV<T₁(H)min<3.3 eV is satisfied.

6. The organic electroluminescent element of claim 2, wherein at least one of the relationships 1.2 eV>ΔIp2>0.2 eV and 1.2 eV>ΔEa2>0.2 eV is satisfied.

7. The organic electroluminescent element of claim 2, wherein at least one of the relationships 1.2 eV>ΔIp2>0.4 eV and 1.2 eV>ΔEa2>0.4 eV is satisfied.

8. The organic electroluminescent element of claim 1, wherein the at least two phosphorescent materials are metal complexes each having a different central metal.

9. The organic electroluminescent element of claim 1, wherein the at least two host compounds include a hole transporting host compound, and the hole transporting host compound is a compound that has, in a molecule, a plurality of carbazole skeletons and aromatic tertiary amine skeletons or a plurality of carbazole skeletons or a plurality of aromatic tertiary amine skeletons.

10. The organic electroluminescent element of claim 2, wherein the at least two host compounds include a hole transporting host compound, and the ionization potential of the hole transporting host compound is in a range of 4.6 to 7.5 eV.

11. The organic electroluminescent element of claim 1, wherein the at least two host compounds include an electron transporting host compound, and the electron transporting host compound is a metal complex, an azole derivative, or an azine derivative.

12. The organic electroluminescent element of claim 2, wherein the at least two host compounds include an electron transporting host compound, and the electron affinity of the electron transporting host compound is in a range of 1.2 to 4.0 eV

13. The organic electroluminescent element of claim 1, wherein the relationships of 4.6 eV<Ip(D1)<7.5 eV and 1.2 eV<Ea(D1)<4.0 eV are satisfied.

14. The organic electroluminescent element of claim 2, wherein the relationships of 4.6 eV<Ip(D2)<7.5 eV and 1.2 eV<Ea(D2)<4.0 eV are satisfied.
